(19) United States
(12) Patent Application Publication
(10) Pub. No.: US 2023/0407457 A1
(43) Pub. Date: Dec. 21, 2023

(54) TREATEMENT OF A POROUS TRANSPORT LAYER FOR USE IN AN ELECTROYLYZER

(71) Applicant: The Regents of the University of California, Oakland, CA (US)

(72) Inventors: Nemanja Danilovic, El Sobrante, CA (US); Keonhag Lee, Berkleley, CA (US); Devashish S. Kulkarni, Irvine, CA (US); Iryna Zenyuk, Irvine, CA (US); Adam Weber, Lafayette, CA (US); Xiong Peng, Berkeley, CA (US)

(21) Appl. No.: 18/332,886

(22) Filed: Jun. 12, 2023

Related U.S. Application Data
(60) Provisional application No. 63/352,743, filed on Jun. 16, 2022.
(60) Provisional application No. 63/492,116, filed on Mar. 24, 2023.

(51) Int. Cl. C23C 14/34; C23C 14/16; C23C 14/02; C25B 11/081; C25B 11/063; C25B 11/052; C25B 11/031; B23K 26/362

(52) U.S. Cl. CPC C23C 14/34; C23C 14/165; C23C 14/028; C25B 11/081; C25B 11/063; C25B 11/052; C25B 11/031; B23K 26/362

(57) ABSTRACT

This disclosure provides systems, methods, and apparatus related to a porous transport layer for use in an electrolyzer. In one aspect, a method includes providing a porous transport layer this is to be a component in an electrolyzer cell. Features are created in a first surface of the porous transport layer. The features serve to increase a surface area of the first surface of the porous transport layer.

### RELATED APPLICATIONS

This application claims priority to U.S. Provisional Patent Application No. 63/352,743, filed Jun. 16, 2022, and to U.S. Provisional Patent Application No. 63/492,116, filed Mar. 24, 2023, both of which are herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### BACKGROUND

A proton exchange membrane (PEM) water electrolyzer is one of the most promising electrolysis techniques for green hydrogen production. When powered by renewables, a PEM electrolyzer cell converts liquid water into hydrogen and oxygen gases in the absence of carbon emissions. Hence, PEM electrolyzers carry enormous potential in leveraging a shift from gray hydrogen to green hydrogen at the heart of energy related sectors.

To achieve this shift towards green hydrogen, cost reduction of PEM electrolyzer technology is needed. With increasing supply of renewables curtailing the cost of electricity, a goal in PEM electrolyzer research is to reduce capital expenditures especially at larger production scales. This requires minimizing voltage losses occurring at higher current densities while significantly reducing precious metal catalyst loadings. Specifically, since the amount of precious materials need in the electrolyzer is predicted to increase substantially at a GW scale, there is a need to improve electrolyzer components so the electrolyzer exhibits low cell potential at lower catalyst loadings.

The interplay of a porous transport layer (PTL) in providing a firm contact at the catalyst layer when the anode catalyst layer is deposited on the proton exchange membrane and facilitating effective mass transport and charge transfer is an important design consideration in the PEM electrolyzer system. The titanium phase in contact with anode catalysts completes a pathway for electrons to transfer to reaction sites. Previous studies show that the contact between the PTL and the catalyst layer significantly impacts the electrolyzer performance, where highly porous interface reduces the electron conductivity thereby lowering catalyst utilization. Conversely, a dense catalyst layer and PTL interface (CL-PTL interface) increases mass transport losses from accumulation of gases over the reaction surface, limiting the transport of liquid water to the reaction surface. One research group demonstrated that these interfacial impacts on electrolyzer performance increase under ultra-low catalyst loadings because the number of reaction sites decreases.

### SUMMARY

Described herein are patterns formed on a surface of a PTL (e.g., a sintered titanium powder-based PTL) using laser ablation. Laser ablation offers an effective method for modifying the macrostructure at the catalyst (CL)-PTL interface, providing similar advantages as PTLs with a microporous layer or a backing layer. Adjusting laser ablation pathways and path spacing (dₚₐₜₕ) generate two distinct interfacial patterns at the CL-PTL interface: a parallel pattern and a cross pattern. Surface morphology of these interfacial patterns were first characterized by observing at the PTL surface as well as the anode side of a catalyst coated membrane post to the electrolyzer operation. The impact of laser ablation on the bulk structure of PTL was also investigated.

Further described herein are methods of fabricating a porous transport electrode (PTE) (a PTE refers to a porous transport layer (PTL) with a catalyst disposed on a surface of the PTL). Previously, to fabricates a PTE, a catalyst ink was made by mixing catalyst nanoparticles, ionomer, and solvent. The catalyst ink was then deposited on a surface of a PTL.

One innovative aspect of the subject matter described in this disclosure can be implemented in a method including providing a porous transport layer, the porous transport layer to be a component in an electrolyzer cell; and creating features in a first surface of the porous transport layer, the features serving to increase a surface area of the first surface of the porous transport layer.

In some embodiments, creating the features is performed using laser ablation.

In some embodiments, the porous transport layer comprises a sintered titanium powder-based porous transport layer, a titanium fiber-based porous transport layer, a nickel fiber-based porous transport layer, or a stainless-steel fiber-based porous transport layer. In some embodiments, the porous transport layer is about 100 microns to 400 microns thick.

In some embodiments, the features are at a depth of about 50 microns to 100 microns in the first surface of the porous transport layer. In some embodiments, the features comprise a plurality of substantially parallel channels in the first surface. In some embodiments, a spacing between a first channel and a second channel of the substantially parallel channels is about 1 micron to 130 microns, and wherein the first channel is adjacent to the second channel. In some embodiments, each of the plurality of substantially parallel channels is about 200 nanometers to 50 microns wide.

In some embodiments, the features comprise a first plurality of substantially parallel channels in the first surface and a second plurality of substantially parallel channels in the first surface, and the second plurality of substantially parallel channels are substantially perpendicular to the first plurality of substantially parallel channels. In some embodiments, a spacing between a first channel and a second channel of the first plurality of substantially parallel channels is about 1 micron to 130 microns, with the first channel being adjacent to the second channel. A spacing between a third channel and a fourth channel of the second plurality of substantially parallel channels is about 1 micron to 130 microns, with the third channel being adjacent to the fourth channel. In some embodiments, each of the first plurality of plurality of substantially parallel channels is about 200 nanometers to 50 microns wide, and each of the second plurality of plurality of substantially parallel channels is about 200 nanometers to 50 microns wide.

In some embodiments, the method further includes creating a plurality of indentations in a second surface of the porous transport layer, where the indentations do not pass from the second surface to the first surface. The plurality of indentations serving to improve gas transport through the porous transport layer. In some embodiments, the plurality of indentations are created using laser ablation. In some embodiments, each indentation of the plurality of the indentations has a circular cross section. In some embodiments, each indentation of the plurality of the indentations passes about half-way from the second surface to the first surface. In some embodiments, a center-to-center distance between two adjacent indentations of the plurality of indentations is about 0.5 millimeters to 1.5 millimeters.

In some embodiments, the method further includes depositing a catalyst on the first surface after creating features in the first surface of the porous transport layer. In some embodiments, the catalyst is deposited on the first surface using a physical vapor deposition process. In some embodiments, the catalyst is deposited on the first surface using a physical vapor deposition process, and the physical vapor deposition process is sputtering. In some embodiments, the catalyst comprises iridium, platinum, ruthenium, or mixtures thereof. In some embodiments, a catalyst loading on the porous transport layer is about 0.03 mg/cm² to 0.4 mg/cm². In some embodiments, the deposited catalyst does not include an ionomer.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a schematic illustration of a water electrolyzer.

FIG. 2 shows an example of a flow diagram illustrating a manufacturing process for modifying a porous transport layer.

FIGS. 3A and 3B shows examples schematic illustrations of patterns formed in a surface of a porous transport layer.

FIG. 4 shows an example of a schematic illustration of indentations formed in the porous transport layer.

FIGS. 5A-5H show example of SEM images of laser ablated sintered titanium porous transport layers. Schematics of laser paths for parallel and cross patterns are as shown in FIG. 5A and FIG. 5E, respectively. Parallel patterns with dₚₐₜₕ=(FIG. 5B) 38 μm, (FIG. 5C) 76 μm, and (FIG. 5D) 127 μm. Wider dₚₐₜₕ imprints more evident land-channel structure at the CL-PTL interface. Cross patterns with dₚₐₜₕ=(FIG. 5F) 38 μm, (FIG. 5G) 76 μm, and (FIG. 5H) 127 μm. Wider dₚₐₜₕ results in more concise checker-like structure at the CL-PTL interface. Laser ablation closes some of the surface pores with the cross paths with dₚₐₜₕ>76 μm. For parallel patterns, smaller dₚₐₜₕ results in more uniform surface while for cross patterns, larger dₚₐₜₕ results in more uniform surface.

FIGS. 6A and 6B show examples of SEM images of bulk-phase architecture modification of a porous transport layer.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

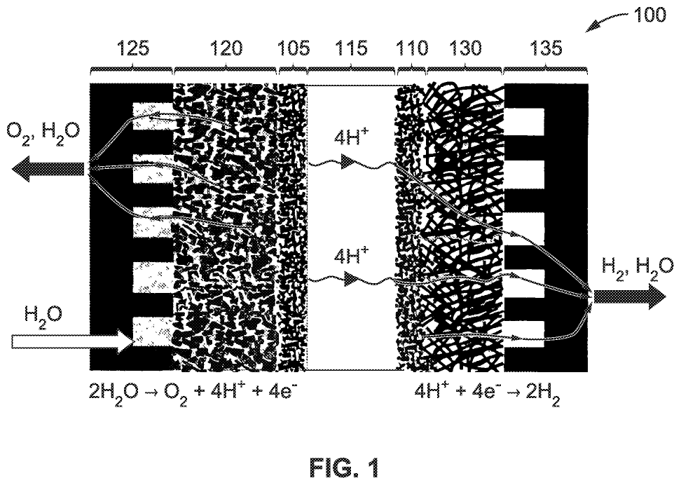

FIG. 1 shows an example of a schematic illustration of a water electrolyzer. Specifically, FIG. 1 shows an example of a schematic illustration of a proton exchange membrane (PEM) water electrolyzer. As shown in FIG. 1, a water electrolyzer 100 includes an anode catalyst layer 105, a cathode catalyst layer 110, and a proton exchange membrane 115. The anode side of the water electrolyzer 100 further includes a porous transport layer 120 (also referred to as an anode porous transport layer) and a material 125 defining an anode flow field. The cathode side of the water electrolyzer 100 further includes a gas diffusion layer 130 (also referred to as a cathode gas diffusion layer) and a material 135 defining a cathode flow field.

In some embodiments, the anode catalyst layer 105 comprises iridium, platinum, ruthenium, or mixtures thereof. In some embodiments, the cathode catalyst layer 110 comprises platinum black, platinum supported by carbon, or mixtures thereof. In some embodiments, the proton exchange membrane 115 comprises a perfluorinated membrane.

In some embodiments, the porous transport layer 120 comprises a sintered titanium powder-based porous transport layer or a titanium fiber-based porous transport layer. In some embodiments, the material 125 defining the anode flow field comprises the same material as the porous transport layer (e.g., titanium).

In some embodiments, the gas transport layer 130 comprises a carbon fiber composite paper or other carbon-based gas diffusion layer. In some embodiments, the material 135 defining the cathode flow field comprises graphite.

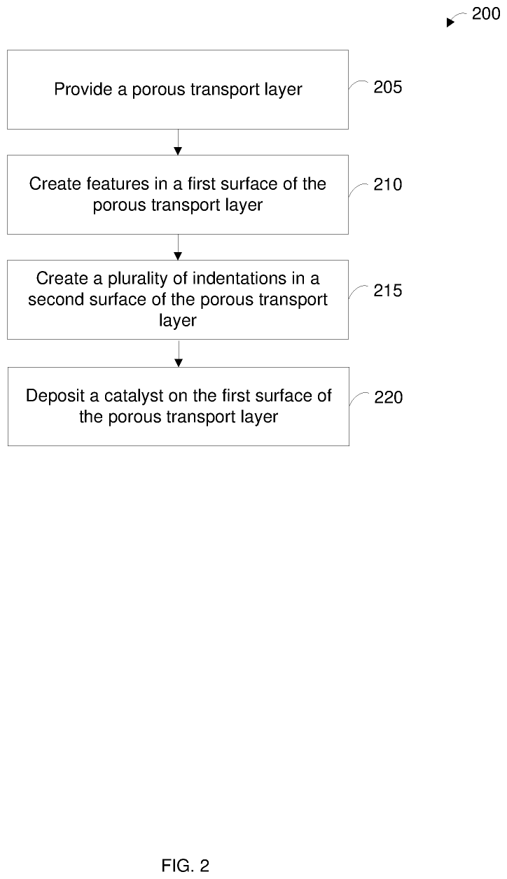

The embodiments described herein are related to modifying the porous transport layer 120 shown in FIG. 1. FIG. 2 shows an example of a flow diagram illustrating a manufacturing process for modifying a porous transport layer. Starting at block 205 of the process 200, a porous transport layer is provided. The porous transport layer is to be a component in an electrolyzer cell. In some embodiment, the electrolyzer cell is a water electrolyzer cell. In some embodiments, the porous transport layer comprises a sintered titanium powder-based porous transport layer. In some embodiments, the porous transport layer comprises a titanium fiber-based porous transport layer. In some embodiments, the porous transport layer comprises a nickel fiber-based porous transport layer. In some embodiments, the porous transport layer comprises a stainless-steel fiber-based porous transport layer. In some embodiments, the porous transport layer is about 100 microns to 400 microns thick, or about 250 microns thick.

At block 210, features are created in a first surface of the porous transport layer. The features serve to increase a surface area of the first surface of the porous transport layer. In some embodiments, the features are created using laser ablation.

The features in the first surface of the porous transport layer can be in any number of different patterns. For example, in some embodiments, the features comprise a plurality of substantially parallel channels in the first surface. In some embodiments, the features are at a depth of about 50 microns to 100 microns in the first surface of the porous transport layer. Note that the features do not pass through the porous transport layer. I.e., the features do not form an open path from the first surface of the porous transport layer to a second surface of the porous transport layer.

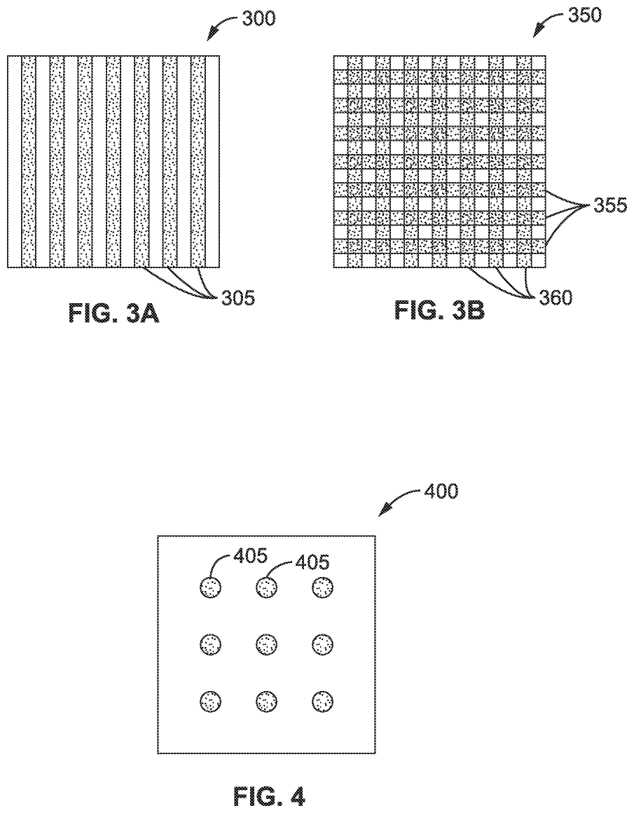

FIGS. 3A and 3B shows examples schematic illustrations of patterns formed in a surface of a porous transport layer. FIG. 3A shows the pattern created in a first surface of the porous transport layer. As shown in FIG. 3A, the first surface 300 of the porous transport layer includes a plurality of substantially parallel channels 305.

In some embodiments, a spacing between a first channel and a second channel of the substantially parallel channels is about 1 micron to 130 microns, with the first channel being adjacent to the second channel. In some embodiments, each of the plurality of substantially parallel channels is about 200 nanometers (nm) to 50 microns.

As another example, in some embodiments, the features comprise a first plurality of substantially parallel channels in the first surface and a second plurality of substantially parallel channels in the first surface. The second plurality of substantially parallel channels are substantially perpendicular to the first plurality of substantially parallel channels. FIG. 3B shows the pattern created in a first surface of the porous transport layer. As shown in FIG. 3B, the first surface 350 of the porous transport layer includes a first plurality of substantially parallel channels 355 and a second plurality of substantially parallel channels 360.

In some embodiments, a spacing between a first channel and a second channel of the first plurality of substantially parallel channels is about 1 micron to 130 microns, with the first channel being adjacent to the second channel. In some embodiments, a spacing between a third channel and a fourth channel of the second plurality of substantially parallel channels is about 1 micron to 130 microns, with the third channel being adjacent to the fourth channel.

In some embodiments, each of the first plurality of plurality of substantially parallel channels is about 200 nanometers to 50 microns wide. In some embodiments, each of the second plurality of plurality of substantially parallel channels is about 200 nanometers to 50 microns wide.

In some embodiments, instead of using laser ablation to create features in the first surface of the porous transport layer, laser ablation is used to remove a layer of the entire first surface of the porous transport layer. Such a process has the effect of making the first surface of the porous transport layer less porous or denser (i.e., more dense). Such a process will also make the first surface of the porous transport layer flatter (i.e., more flat). When a catalyst is deposited on such a first surface of the porous transport layer, less catalyst will be deposited in the inner structure of the porous transport layer. Further, the catalyst only functions when it is in contact with the proton exchange membrane. A porous transport layer with a flatter surface will enable more of the catalyst to be in contact with the proton exchange membrane, allowing for better utilization of the catalyst.

In some embodiments, a catalyst is deposited on the first surface of the porous transport layer (e.g., with the operation described at block 220 or a different method) and then then the porous transport layer in incorporated in an electrolyzer.

In some embodiments, the process 200 continues at block 215 with a plurality of indentations being created in a second surface of the porous transport layer. The indentations do not pass from the second surface to the first surface. The plurality of indentations serve to improve gas transport through the porous transport layer.

FIG. 4 shows an example of a schematic illustration of indentations formed in a surface of the porous transport layer. As shown in FIG. 4, a second surface 400 of the porous transport layer includes a plurality of indentations 405. In some embodiments, the plurality of indentations are created using laser ablation. In some embodiments, the second surface of the porous transport layer faces the anode flow field side of an electrolyzer.

In some embodiments, each indentation of the plurality of the indentations has a circular cross section. In some embodiments, each indentation of the plurality of the indentations passes about half-way from the second surface to the first surface or the porous transport layer. In some embodiments, a center-to-center distance between two adjacent indentations of the plurality of indentations is about 0.5 millimeters to 1.5 millimeters, or about 1 millimeter.

In some embodiments, the process 200 continues at block 220 with depositing a catalyst on the first surface of the porous transport layer. In some embodiments, the operation at block 220 is performed after features are created in the first surface of the porous transport layer.

In some embodiments, the catalyst is deposited on the first surface using a physical vapor deposition process. In some embodiments, the physical vapor deposition process is sputtering. Using a physical vapor deposition process to deposit the catalyst on the porous transport layer allows the catalyst to be depositing without incorporating an ionomer. That is, the physical deposition process does not use an ionomer and the deposited catalyst does not include an ionomer. A catalyst that does not include an ionomer disposed on a surface of a porous transport layer may allow the porous transport layer to be more easily reused or the catalyst to be more easily recycled.

For example, a porous transport layer having a catalyst (the catalyst not including an ionomer) disposed thereon could be used in a first water electrolyzer. If the first electrolyzer fails, it may be possible to deposit more catalyst on the porous transport layer and use the porous transport layer in a second in water electrolyzer. As another example, the catalyst can be more easily recycled when the catalyst does not include an ionomer (e.g., when recycling a catalyst that includes an ionomer, processing the ionomer can create toxic compounds).

In some embodiments, the catalyst comprises iridium. In some embodiments, the catalyst comprises iridium, platinum, ruthenium, or mixtures thereof. In some embodiments, the catalyst loading on the porous transport layer is about 0.03 mg/cm² to 0.4 mg/cm².

Alternative methods could also be used to deposit a catalyst on the first surface of a porous transport layer after block 205, block 210, or block 215. Further, in some embodiments, a method includes only blocks 205 and 220. In some embodiments, a method includes only blocks 205, 210, and 220. In some embodiments, a method includes only blocks 205, 215, and 220.

Note that while the embodiments described herein are described with respect to a water electrolyzer, the embodiments can also be implemented with other electrolyzers (e.g., a carbon dioxide electrolyzer or an alkaline water electrolyzer).

The following examples are intended to be examples of the embodiments described herein, and are not intended to be limiting.

### Example—Laser Ablation of Porous Transport Layers (PTLs)

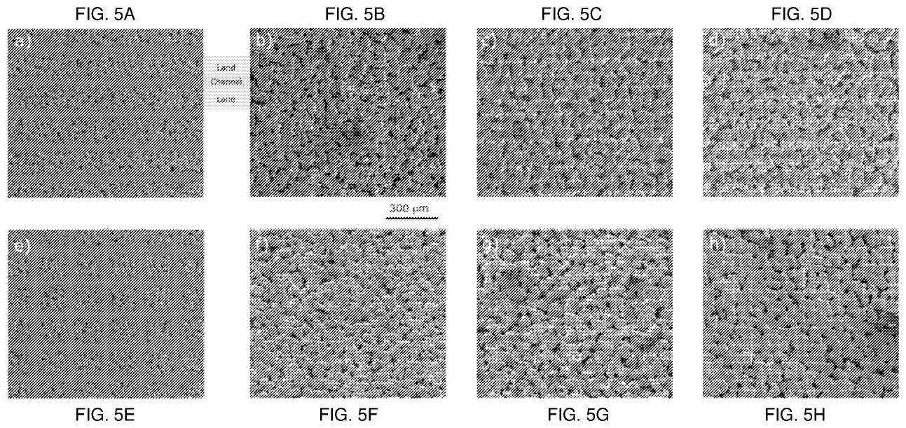

The surface of a sintered titanium powder-based PTL was ablated using a class 4 fiber laser cutter. Laser power of 5 W at a frequency of 20 kHz was applied to fabricate both a parallel pattern and a cross pattern on the surface of PTLs. 100 passes were sufficient to modify the morphology of the PTL as shown in FIGS. 5A-5H. The patterned pore PTL was fabricated by laser ablating 400 pores with a diameter of 200 μm at the PTL-flow field interface. The pores were fabricated in an array of 20 by 20 pores with center-to-center distance being 1 mm. The laser power was set to 5 W at a frequency of 20 kHz and 600 passes were applied. Post to the laser ablation, the PTLs were rinsed first with isopropanol and then with deionized (DI) water. After rinsing, PTLs were submerged in isopropanol for 30 min and underwent chemical etching for 3 min using a commercial Ti metal etchant.

### Example—Laser Ablated Porous Transport Layers

Controlling laser ablation pathways and dₚₐₜₕ resulted in two distinct patterns at the CL-PTL interface as shown in FIGS. 5A-5H. Laser ablation in parallel patterns imprinted land-channel structure on the PTL (FIGS. 5B-5D), and laser ablation in cross patterns inscribed checker-like structure on the PTL (FIG. 5F-5H). The PTL surface affected by the laser became smooth, while the surface unaffected by the laser, such as the land region in FIGS. 5B and 5C, maintained its original roughness. Controlling dₚₐₜₕ dictated the exposure of the PTL surface to laser ablation, and a large change in dₚₐₜₕ resulted in a different PTL morphology albeit undergoing the identical laser ablation pathway as seen in FIGS. 5A-5H.

Ablating laser in parallel paths formed land-channel structure at the CL-PTL interface. Specifically, laser ablation smoothed out the channel region, providing enhanced connectivity to the pores in the PTL, which facilitates the gas removal process. Also, the land structure increases interfacial surface contact area between the PTL and the catalyst layer. Widths of the land region increased when dₚₐₜₕ increased, where the PTL with dₚₐₜₕ=127 μm exhibited the largest land features and the PTL with dₚₐₜₕ=38 μm barely showed land-channel structure. Since the overall number of laser paths increased with shorter dₚₐₜₕ, the PTL with dₚₐₜₕ=38 μm resulted in a more of a granular structure from laser melting titanium powders on the surface, which further reduced the surface roughness of the PTL. Compared to the pristine PTL (FIG. 5E), the pores in parallel patterned PTLs show higher connectivity.

In cross patterned PTLs, laser ablation imprinted a checker-like structure. Longer dₚₐₜₕ decreased surface roughness of the PTL and flattened the PTL interface. The cross pattern PTL with dₚₐₜₕ=127 μm effectively melted the titanium particles resulting in closure of many surface pores at the PTL interface, which can effectively enhance the contact with the catalyst layer. This structure also minimizes membrane deformation into the PTL interface and prevents catalyst layer deformation within the large pores of conventional PTL structures, which decreases electrical and ionic conductivity within the catalyst layer. Membrane deformation could also lead to local membrane thinning, therefore leaching fluoride ions, which in return exacerbates electrolyzer component degradation.

When dₚₐₜₕ decreases, surface roughness increases and the interface gains more a granular structure. Specifically, increased number of laser paths from having shorter dₚₐₜₕ over-melt the PTL interface, causing formation of tiny pores within titanium phase that appear to be dead-ended. Dead-ended pores block transport of both liquid water and oxygen gas, which causes loss of effective interfacial contact between PTL and CL.

### Example—Bulk-Phase Architecture Modification of the Porous Transport Layer

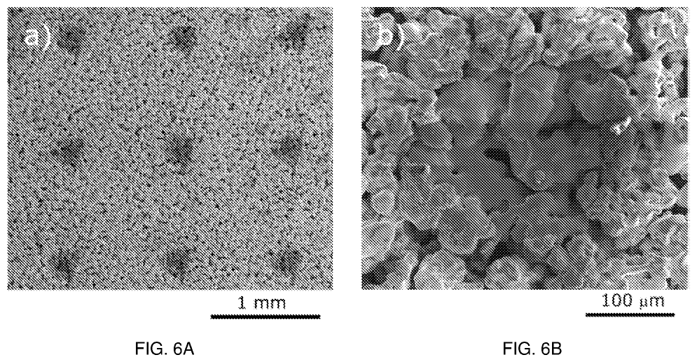

This example describes modifying the bulk-phase architecture of PTLs by implementing patternable half-through pore at the flow field-PTL interfaces. Previous studies have shown that modifying pore structure to enhance mass transport comes at a cost of losing CL-PTL interfacial contact due to the trade-off relationship between interfacial contact and mass transport. In fact, some studies highlight that performance lost from the CL-PTL interfacial contact is significantly more harmful to the electrolyzer performance than the improvement obtained from the improved mass transport. Moreover, some studies demonstrate that these pore structures exacerbate mass transport losses emanated from having poor interfacial contact. Therefore, there is a need for a technique to balance PTL bulk-phase porosity and tortuosity to gain in mass transport and the PTL-CL interfacial contact to enhance electrode kinetics and catalyst utilization. Applying laser-ablation at the flow field-PTL interface to fabricate half-through could help improve the overall PTL porosity and reduce PTL tortuosity while maintaining the PTL-CL interfacial properties. The patterned half-through pore PTL improved mass transport during electrolysis with having minimal impact on the CL-PTL interface. FIGS. 6A and 6B show examples of SEM images of bulk-phase architecture modification of a porous transport layer.

### Example—Ir Porous Transport Electrode (PTE) Fabrication

As used below, a porous transport electrode (PTE) refers to a porous transport layer with a catalyst disposed on a surface of the porous transport layer (PTL). An ionomer-free iridium porous transport electrode was prepared by sputtering Jr onto a commercially available sintered titanium powder-based PTL. Prior to Ir sputtering, the PTL was cleaned using a commercial etchant for 2 minutes, rinsed in Milli-Q deionized water (18.2 MΩ·cm) for 2 minutes, and was left to air dry. Ir was sputtered onto the PTL using sputtering system equipped with an Ir target. A deposition rate of 1.75 Å/sec was obtained at 3 mTorr and at room temperature under an argon atmosphere. Ir coating duration was controlled for 3, 5, 10, 20, and min to achieve targeted loadings of 0.033, 0.05, 0.085, 0.187, and 0.037 mg_{Ir}/cm², respectively. The iridium loading was measured using X-ray fluorescence spectroscopy.

A laser ablated Ir PTE was fabricated by depositing Ir onto the laser-ablated surface of a PTL. A class 4 fiber laser cutter was used for the laser-ablation process. The PTL was ablated in a cross pattern with spacing between each path set to 0.003 in. First 10 passes were applied at power of 25 W at 80 kHz to melt away the titanium phase, and 60 passes were applied at power of 5 W at 80 kHz to remove burrs created from laser ablation and smooth the surface. After the laser-ablation process, the PTL was rinsed first with isopropanol and then with DI water. The PTL was submerged in isopropanol for 30 min and then underwent Ir coating process as described above.

### Example—Tailoring the Surface Compositions of Ir PTEs

To adjust the Ir PTE surface composition and understand its potential impact on proton exchange membrane (PEM) water electrolyzer performance, a post thermal treatment in air from 200 to 500° C. was conducted. As sintering temperature increased, there was an increase of iridium oxide in the PTE as indicated by XPS measurements. However, XRD only shows the presence of metallic Ir, implying either very thin or amorphous oxide formation after thermal annealing. XRD measurements also show increases in Ir crystallinity as more existence of diffraction peaks of (200) and (220) at higher temperatures.

The change in electrolyzer performance with sintering temperature was subtle up to 400° C., even with increased content of iridium oxide in the catalyst layer. From Tafel plots, the measured Tafel slopes increased with increased oxide in iridium. This is likely due to the decrease of metallic Ir content and increase of oxide content, which is less active for the oxygen evolution reaction. For the PTE sintered at 500° C., a very thick oxide layer formed on the titanium phase in the PTL, which significantly decreased the electronic conductivity and translated to high ohmic loss in the polarization curve. A hint of blue oxide layer was seen on the back side of the PTL sintered at 500° C.

### CONCLUSION

Further details regarding the embodiments described herein can be found in Jason K. Lee et al., “Interfacial engineering via laser ablation for high-performing PEM water electrolysis,” Applied Energy, Volume 336, 2023, 120853, which is hereby incorporated by reference.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A method comprising:
providing a porous transport layer, the porous transport layer to be a component in an electrolyzer cell; and
creating features in a first surface of the porous transport layer, the features serving to increase a surface area of the first surface of the porous transport layer.

2. The method of claim 1, wherein creating the features is performed using laser ablation.

3. The method of claim 1, wherein the porous transport layer comprises a sintered titanium powder-based porous transport layer, a titanium fiber-based porous transport layer, a nickel fiber-based porous transport layer, or a stainless-steel fiber-based porous transport layer.

4. The method of claim 1, wherein the porous transport layer is about 100 microns to 400 microns thick.

5. The method of claim 1, wherein the features are at a depth of about 50 microns to 100 microns in the first surface of the porous transport layer.

6. The method of claim 1, wherein the features comprise a plurality of substantially parallel channels in the first surface.

7. The method of claim 6, wherein a spacing between a first channel and a second channel of the substantially parallel channels is about 1 micron to 130 microns, and wherein the first channel is adjacent to the second channel.

8. The method of claim 6, wherein each of the plurality of substantially parallel channels is about 200 nanometers to 50 microns wide.

9. The method of claim 1, wherein the features comprise a first plurality of substantially parallel channels in the first surface and a second plurality of substantially parallel channels in the first surface, and wherein the second plurality of substantially parallel channels are substantially perpendicular to the first plurality of substantially parallel channels.

10. The method of claim 9, wherein a spacing between a first channel and a second channel of the first plurality of substantially parallel channels is about 1 micron to 130 microns, wherein the first channel is adjacent to the second channel, wherein a spacing between a third channel and a fourth channel of the second plurality of substantially parallel channels is about 1 micron to 130 microns, and wherein the third channel is adjacent to the fourth channel.

11. The method of claim 9, wherein each of the first plurality of plurality of substantially parallel channels is about 200 nanometers to 50 microns wide, and wherein each of the second plurality of plurality of substantially parallel channels is about 200 nanometers to 50 microns wide.

12. The method of claim 1, further comprising:
creating a plurality of indentations in a second surface of the porous transport layer, wherein the indentations do not pass from the second surface to the first surface, and wherein the plurality of indentations serve to improve gas transport through the porous transport layer.

13. The method of claim 12, wherein the plurality of indentations are created using laser ablation.

14. The method of claim 12, wherein each indentation of the plurality of the indentations passes about half-way from the second surface to the first surface.

15. The method of claim 12, wherein a center-to-center distance between two adjacent indentations of the plurality of indentations is about 0.5 millimeters to 1.5 millimeters.

16. The method of claim 1, further comprising:
after creating features in the first surface of the porous transport layer, depositing a catalyst on the first surface.

17. The method of claim 16, wherein the catalyst is deposited on the first surface using a physical vapor deposition process.

18. The method of claim 16, wherein the catalyst is deposited on the first surface using a physical vapor deposition process, and wherein the physical vapor deposition process is sputtering.

19. The method of claim 16, wherein the catalyst comprises iridium, platinum, ruthenium, or mixtures thereof.

20. The method of claim 16, wherein a catalyst loading on the porous transport layer is about 0.03 mg/cm² to 0.4 mg/cm².
